(19) United States
(12) Patent Application Publication
(10) Pub. No.: US 2026/0254411 A1
(43) Pub. Date: Aug. 27, 2026

(54) DISTRIBUTED POWER MANAGEMENT CIRCUIT

(71) Applicant: Qorvo US, Inc., Greensboro, NC (US)

(72) Inventors: Daniel E. Brueske, Winston-Salem, NC (US); Nadim Khlat, Ceret (FR)

(21) Appl. No.: 19/126,808

(22) PCT Filed: Oct. 6, 2023
(86) PCT No.: PCT/US2023/034650

§ 371 Date: May 2, 2025

Related U.S. Application Data
(60) Provisional application No. 63/386,573, filed on Dec. 8, 2022.
(60) Provisional application No. 63/491,438, filed on Mar. 21, 2023.

(51) Int. Cl. H03F 1/02; H03F 3/24; H04B 1/04; H04B 7/06; H04L 25/49

(52) U.S. Cl. CPC H03F 1/0238; H03F 3/245; H04B 1/0475; H04B 7/0602; H04L 25/4902; H03F 2200/105; H03F 2200/451; H04B 2001/045

(57) ABSTRACT

A distributed power management circuit is provided. The distributed power management circuit includes a main power management integrated circuit (PMIC) and a distributed PMIC separated from the main PMIC. The main PMIC is coupled to the distributed PMIC via a conductive path. Notably, a parasitic capacitance of the main PMIC can interact with a trace inductance of the conductive path to cause an equivalent notch that can degrade linearity performance of the distributed PMIC. In this regard, in embodiments disclosed herein, a deQ circuit is provided in the distributed power management circuit to reduce a quality factor (Q-factor) of the equivalent notch to thereby improve linearity performance of the distributed PMIC. Further, the deQ circuit can be so configured to increase an open loop gain of the distributed PMIC to help reduce current flow in the distributed PMIC to thereby improve overall energy efficiency of the distributed power management circuit.

### RELATED APPLICATIONS

This application claims the benefit of U.S. provisional patent application Ser. No. 63/386,573, filed on Dec. 8, 2022, and the benefit of U.S. provisional patent application Ser. No. 63/491,438, filed on Mar. 21, 2023, the disclosures of which are hereby incorporated herein by reference in their entireties.

### FIELD OF THE DISCLOSURE

The technology of the disclosure relates generally to a distributed power management circuit and, more specifically, a distributed power management circuit including a main power management integrated circuit (PMIC) and a distributed PMIC.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as fifth-generation new-radio (5G-NR) technology configured to communicate a millimeter wave (mmWave) radio frequency (RF) signal(s) in an mmWave spectrum located above 12 GHz frequency. To achieve higher data rates, a mobile communication device may employ a power amplifier(s) to increase output power of the mmWave RF signal(s) (e.g., maintaining sufficient energy per bit).

Envelope tracking (ET) and average power tracking (APT) are power management techniques designed to improve efficiency levels of power amplifiers to help reduce power consumption and thermal dissipation in a power management circuit. In a typical power management circuit, a power amplifier(s) is configured to amplify an RF signal(s) based on a time-variant voltage(s) that tracks a time-variant envelope of the RF signal(s). Understandably, the better the time-variant voltage(s) tracks the time-variant power envelope(s), the higher linearity the power amplifier(s) can achieve, particularly when the RF signal(s) is modulated across a wide modulation bandwidth (e.g., >100 MHz).

### SUMMARY

Embodiments of the disclosure relate to a distributed power management circuit. The distributed power management circuit includes a main power management integrated circuit (PMIC) and a distributed PMIC separated from the main PMIC. The main PMIC is coupled to the distributed PMIC via a conductive path. Notably, a parasitic capacitance of the main PMIC can interact with a trace inductance of the conductive path to cause an equivalent notch that can degrade linearity performance of the distributed PMIC. In this regard, in embodiments disclosed herein, a deQ circuit is provided in the distributed power management circuit to reduce a quality factor (Q-factor) of the equivalent notch to thereby improve linearity performance of the distributed PMIC. Further, the deQ circuit can be so configured to increase open loop gain of the distributed PMIC to help reduce current flow in the distributed PMIC to thereby improve overall energy efficiency of the distributed power management circuit.

In one aspect, a distributed power management circuit is provided. The distributed power management circuit includes a distributed PMIC. The distributed PMIC is configured to generate a distributed voltage based on a distributed target voltage. The distributed power management circuit also includes a main PMIC. The main PMIC is configured to generate the distributed target voltage and provide a low-frequency current to the distributed PMIC via a conductive path provided between the main PMIC and the distributed PMIC. The distributed power management circuit also includes a deQ circuit. The deQ circuit is provided between the distributed PMIC and the main PMIC. The deQ circuit is configured to resonate at a series resonance frequency to reduce a quality factor, Q-factor, of an equivalent notch collectively caused by an equivalent inductance of the conductive path and an equivalent capacitance of the main PMIC.

In another aspect, a wireless device is provided. The wireless device includes at least one primary antenna provided on a first side of the wireless device. The wireless device also includes at least one secondary antenna provided on a second side of the wireless device. The wireless device also includes at least one primary power amplifier circuit. The at least one primary power amplifier circuit is configured to amplify a radio frequency, RF, signal based on a voltage for transmission via the at least one primary antenna. The wireless device also includes at least one distributed power amplifier circuit. The at least one distributed power amplifier circuit is configured to amplify the RF signal based on a distributed voltage for transmission via the at least one secondary antenna. The wireless device also includes a distributed power management circuit. The distributed power management circuit includes a distributed PMIC. The distributed PMIC is configured to generate the distributed voltage based on a distributed target voltage and provide the distributed voltage to the at least one distributed power amplifier circuit. The distributed power management circuit also includes a main PMIC. The main PMIC is configured to generate and provide the voltage to the at least one primary power amplifier circuit. The main PMIC is also configured to generate the distributed target voltage and provide a low-frequency current to the distributed PMIC via a conductive path provided between the main PMIC and the distributed PMIC. The distributed power management circuit also includes a deQ circuit. The deQ circuit is provided between the distributed PMIC and the main PMIC. The deQ circuit is configured to resonate at a series resonance frequency to reduce a quality factor, Q-factor, of an equivalent notch collectively caused by an equivalent inductance of the conductive path and an equivalent capacitance of the main PMIC.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of a wireless device wherein an equivalent notch presenting in an existing distributed power management circuit can degrade overall linearity performance of the wireless device;

FIGS. 2A and 2B are schematic diagrams of an exemplary distributed power management circuit, which can be provided in the wireless device of FIG. 1 to effectively reduce the Q-factor of the equivalent notch;

FIG. 3 is a schematic diagram of an exemplary deQ network in a deQ circuit of the distributed power management circuit of FIGS. 2A and 2B;

FIGS. 4A-4C are graphic diagrams providing exemplary illustrations as to how the deQ circuit in FIG. 3 can impact overall performance of the distributed power management circuit of FIGS. 2A and 2B;

FIG. 5 is a schematic diagram of an exemplary distributed control circuit in the distributed power management circuit of FIGS. 2A and 2B; and

FIG. 6 is a schematic diagram of an exemplary user element wherein the distributed power management circuit of FIGS. 2A and 2B can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a distributed power management circuit. The distributed power management circuit includes a main power management integrated circuit (PMIC) and a distributed PMIC separated from the main PMIC. The main PMIC is coupled to the distributed PMIC via a conductive path. Notably, a parasitic capacitance of the main PMIC can interact with a trace inductance of the conductive path to cause an equivalent notch that can degrade linearity performance of the distributed PMIC. In this regard, in embodiments disclosed herein, a deQ circuit is provided in the distributed power management circuit to reduce a quality factor (Q-factor) of the equivalent notch to thereby improve linearity performance of the distributed PMIC. Further, the deQ circuit can be so configured to increase an open loop gain of the distributed PMIC to help reduce current flow in the distributed PMIC to thereby improve overall energy efficiency of the distributed power management circuit.

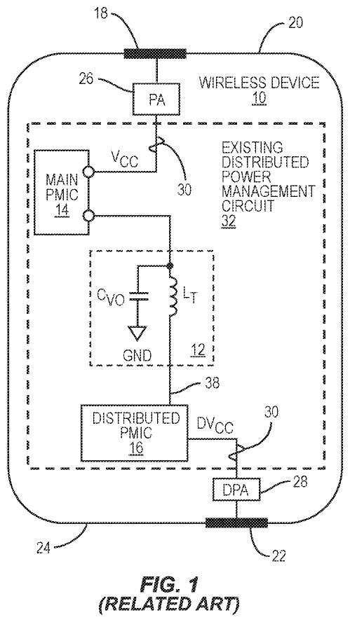

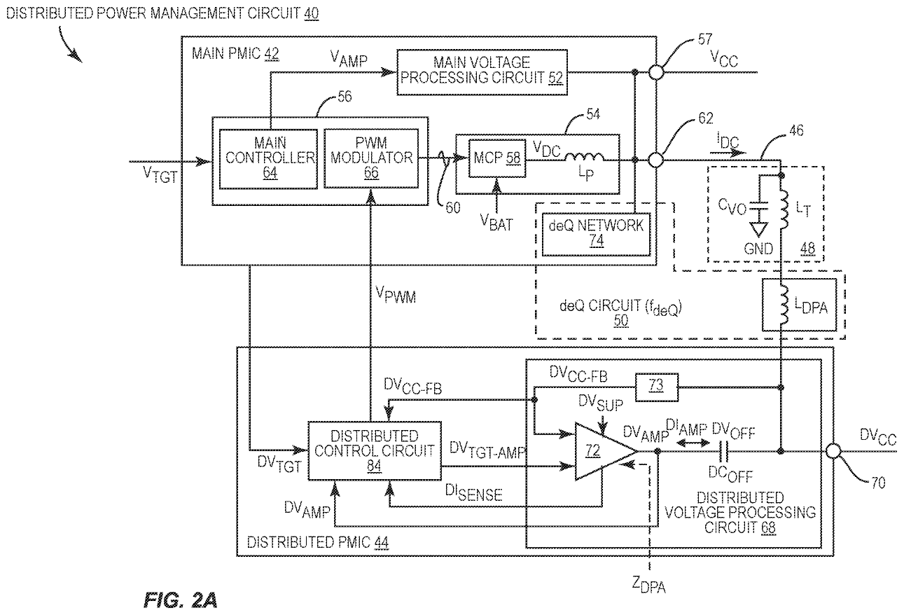

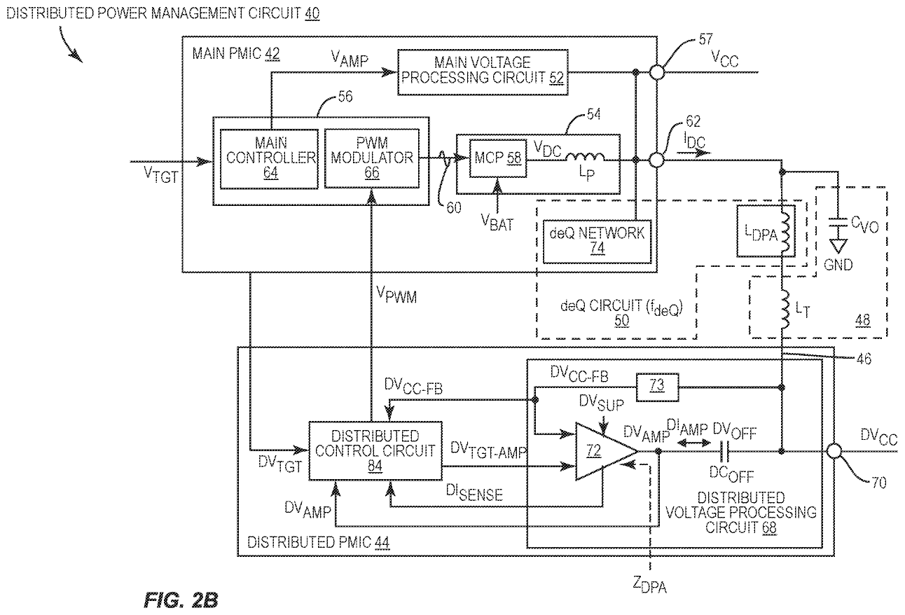

Before discussing the distributed power management circuit of the present disclosure, starting at FIG. 2A, a brief discussion of a wireless device incorporating an existing distributed power management circuit is first provided in FIG. 1 to help understand how an unwanted equivalent notch between a main PMIC and a distributed PMIC can impact overall linearity performance of the wireless device.

FIG. 1 is a schematic diagram of a wireless device 10 wherein an equivalent notch 12 between a main PMIC 14 and a distributed PMIC 16 can degrade overall linearity performance of the wireless device 10. In a non-limiting example, the wireless device 10 can include at least one primary antenna 18 disposed on a first side 20 (e.g., top side) of the wireless device 10 and at least one secondary antenna 22 disposed on a second side 24 (e.g., bottom side) of the wireless device 10. Notably, the primary antenna 18 and the secondary antenna 22 are so disposed to help mitigate a so-called hand-blocking effect in the wireless device 10.

The wireless device 10 also includes at least one primary power amplifier circuit 26 and at least one distributed power amplifier circuit 28. The primary power amplifier circuit 26 is provided next to the primary antenna 18 to amplify a radio frequency (RF) signal 30 based on a voltage V_{CC} for transmission via the primary antenna 18. The distributed power amplifier circuit 28 is provided next to the secondary antenna 22 to amplify the RF signal 30 based on a distributed voltage D_{VCC} for transmission via the secondary antenna 22. Notably, the wireless device 10 is configured to transmit the RF signal 30 via either the primary antenna 18 (when the secondary antenna 22 is blocked) or the secondary antenna 22 (when the primary antenna 18 is blocked).

The wireless device 10 further includes an existing distributed power management circuit 32 that includes the main PMIC 14 and the distributed PMIC 16. Specifically, the main PMIC 14 is provided closer to the primary power amplifier circuit 26 than to the distributed power amplifier circuit 28. In contrast, the distributed PMIC 16 is provided closer to the distributed power amplifier circuit 28 than to the primary power amplifier circuit 26.

The main PMIC 14 is coupled to the distributed PMIC 16 via a conductive path 38 (e.g., a conductive trace). As such, the distributed PMIC 16 will see the equivalent notch 12 that is caused by an equivalent trace inductance L_{T} of the conductive path 38 and an equivalent capacitance C_{VO} (e.g., parasitic capacitance) of the main PMIC 14. Notably, the equivalent notch 12 is shown herein to represent a collective effect of the equivalent trace inductance L_{T} and the equivalent capacitance C_{VO}, as opposed to indicating an actual physical circuit.

The equivalent notch 12 can resonate at an equivalent series resonance frequency f_{RESONANCE} and correspond to a Q-factor as shown in the equations (Eq. 1 and Eq. 2) below.

$${f}_{RESONANCE} = 1 / ( 2 π \sqrt{{L}_{T} * {C}_{VO}} ) \qquad ( Eq . 1 )$$

$$Q - factor {=}^{def} {f}_{RESONANCE} / {f}_{BWIDTH} \qquad ( Eq . 2 )$$

As shown in the equation (Eq. 2), the Q-factor of the equivalent notch 12 is proportionally related to the equivalent series resonance frequency f_{RESONANCE} and a modulation bandwidth f_{BWIDTH} of the distributed PMIC 16. When the equivalent series resonance frequency f_{RESONANCE} is close to the bandwidth f_{BWIDTH}, the Q-factor will increase accordingly. In contrast, when the equivalent series resonance frequency f_{RESONANCE} is separated from the modulation bandwidth f_{BWIDTH}, the Q-factor will decrease accordingly. Understandably, when the equivalent series resonance frequency f_{RESONANCE} is close enough to the modulation bandwidth f_{BWIDTH}, the equivalent notch 12 can cause linearity degradation in the distributed PMIC 16 and, therefore in the distributed power amplifier circuit 28. Since it may be difficult to completely eliminate the equivalent notch 12, it is thus desirable to reduce the Q-factor of the equivalent notch 12 as much as possible to help avoid, or at least mitigate, the linearity degradation in the distributed PMIC 16 and the distributed power amplifier circuit 28.

In this regard, FIG. 2A is a schematic diagram of an exemplary distributed power management circuit 40, which can replace the existing distributed power management circuit 32 in the wireless device 10 of FIG. 1 to effectively reduce the Q-factor of the equivalent notch 12. Herein, the distributed power management circuit 40 includes a main PMIC 42, a distributed PMIC 44, and a conductive path 46 (e.g., conductive trace) that couples the main PMIC 42 with the distributed PMIC 44. In a non-limiting example, the main PMIC 42 can be functionally equivalent to the main PMIC 14 in FIG. 1 and be disposed closer to the primary power amplifier circuit 26, and the distributed PMIC 44 can be functionally equivalent to the distributed PMIC 16 in FIG. 1 and be disposed closer to the distributed power amplifier circuit 28.

Since the main PMIC 42 is coupled to the distributed PMIC 44 by the conductive path 46, there also exists an equivalent notch 48 between the main PMIC 42 and the distributed PMIC 44. Like the equivalent notch 12 in FIG. 1, the equivalent notch 48 is collectively caused by an equivalent trace inductance L_{T} of the conductive path 46 and an equivalent capacitance C_{VO} of the main PMIC 42. Accordingly, the equivalent notch 48 will be associated with a Q-factor as described by the equation (Eq. 2) above. Thus, the equivalent notch 48 will cause the same linearity problem to the distributed PMIC 44 as previously described in FIG. 1.

To help reduce the Q-factor of the equivalent notch 48, the distributed power management circuit 40 is configured according to an embodiment of the present disclosure to further include a deQ circuit 50. In context of the present disclosure, “deQ” is an abbreviation for “decreasing Q-factor.” As described in detail below, the deQ circuit 50 is configured to resonate at a series resonance frequency f_{deQ} to effectively reduce the Q-factor of the equivalent notch 48. In addition, the deQ circuit 50 can also be configured to increase the open loop gain of the distributed PMIC 44 to thereby reduce the current flow in the distributed PMIC 44. As a result, it is possible to improve linearity performance of the distributed PMIC 44 and overall energy efficiency of the distributed power management circuit 40. Further, the deQ circuit 50 can help reduce a peak voltage seen by the main PMIC 42 to thereby protect the main PMIC 42 from exceeding an inherently safe operating region. In a non-limiting example, the deQ circuit 50 can protect the main PMIC 42 from a breakdown voltage (a.k.a. BVDSS). Herein, the breakdown voltage is a voltage that can cause a reverse-biased body-drift diode to break down and allow significant current to flow between a source and a drain of a metal-oxide-semiconductor field-effect transistor (MOSFET) by the avalanche multiplication process while the gate and the source of the MOSFET are shorted together.

In an embodiment, the main PMIC 42 includes a main voltage processing circuit 52, a switcher circuit 54, and a main control circuit 56. Herein, the main voltage processing circuit 52 is configured to generate a voltage V_{CC} at a primary voltage output 57 based on an amplifier target voltage V_{AMP}. The switcher circuit 54 includes a multi-level charge pump (MCP) 58 and a power inductor L_{P}. Specifically, the MCP 58 is configured to generate a low-frequency voltage V_{DC} as a function of a battery voltage V_{BAT} and in accordance with a duty cycle signal 60 (e.g., a sawtooth signal). The power inductor L_{P} is coupled to an auxiliary voltage output 62 and configured to induce a low-frequency current I_{DC} at the auxiliary voltage output 62 based on the low-frequency voltage V_{DC}. Herein, the auxiliary voltage output 62 is further coupled to the conductive path 46 such that the low-frequency current loc can be provided to the distributed PMIC 44 via the conductive path 46.

In a non-limiting example, the MCP 58 can be a buck-boost direct-current-direct-current (DC-DC) converter that can operate in a buck mode and/or a boost mode. When operating in the buck mode, the MCP 58 can generate the low-frequency voltage V_{DC} at 0×V_{BAT} (i.e., 0 V) or 1×V_{BAT} (i.e., V_{BAT}). When operating in the boost mode, the MCP 58 can generate the low-frequency voltage V_{DC} at 2×V_{BAT} (i.e., 2V_{BAT}). The duty cycle signal 60 can be so determined to cause the MCP 58 to alternate between generating the low-frequency voltage V_{DC} at 0×V_{BAT}, 1×V_{BAT}, and/or 2V_{BAT}. For example, the duty cycle signal 60 can be determined to cause the MCP 58 to generate the low-frequency voltage V_{DC} as an average of 30% @0×V_{BAT}, 30% @1×V_{BAT}, and 40% @2×V_{BAT}. Thus, by adapting the duty cycle signal 60, it is possible to control the low-frequency voltage V_{DC} and thus the low-frequency current I_{DC}.

In an embodiment, the main control circuit 56 includes a main controller 64 and a pulse-width modulation (PWM) modulator 66. The main controller 64, which can be a bang-bang controller (BBC) as an example, is configured to generate the amplifier target voltage V_{AMP} based on a target voltage V_{TGT} that sets a target for the voltage V_{CC}. In a non-limiting example, the main controller 64 can receive the target voltage V_{TGT} from a transceiver circuit (not shown). The PWM modulator 66, on the other hand, is configured to generate the duty cycle signal 60 based on a PWM target voltage V_{PWM}. As described in detail later on, the PWM target voltage V_{PWM} is provided to the PWM modulator 66 by the distributed PMIC 44 to help regulate the low-frequency current loc provided to the distributed PMIC 44.

The distributed PMIC 44 includes a distributed voltage processing circuit 68. The distributed voltage processing circuit 68 is configured to generate a distributed voltage DV_{CC} at a distributed voltage output 70 based on a distributed amplifier target voltage DV_{TGT-AMP}. Specifically, the distributed voltage processing circuit 68 includes a distributed voltage amplifier 72 and a distributed offset capacitor D_{COFF}. The distributed voltage amplifier 72 is configured to generate a distributed initial voltage DV_{AMP} based on the distributed amplifier target voltage DV_{TGT-AMP}, which sets a target for the distributed initial voltage DV_{AMP}, and a distributed supply voltage DV_{SUP}. The distributed offset capacitor D_{COFF} is coupled between the distributed voltage amplifier 72 and the distributed voltage output 70. In an embodiment, the distributed offset capacitor D_{COFF} is configured to raise the distributed initial voltage DV_{AMP} by a distributed offset voltage DV_{OFF} to thereby generate the distributed voltage DV_{CC} at the distributed voltage output 70 (DV_{CC}=DV_{AMP}+DV_{OFF}). The distributed voltage processing circuit 68 also includes a feedback path 73 configured to provide a feedback DV_{CC-FB} of the distributed voltage DV_{CC} to the distributed voltage amplifier 72.

Herein, the distributed offset capacitor D_{COFF} may be charged by the low-frequency current I_{DC} and/or a distributed high-frequency current DI_{AMP} sourced by the distributed voltage amplifier 72 to raise the distributed offset voltage DV_{OFF}. The distributed offset capacitor D_{COFF} may also be discharged by the distributed high-frequency current DI_{AMP} sunk into the distributed voltage amplifier 72 to reduce the distributed offset voltage DV_{OFF}. In an embodiment, the distributed voltage amplifier 72 is configured to generate a distributed sense current DI_{SENSE} to indicate an actual amount of the distributed high-frequency current DI_{AMP} being sourced or sunk by the distributed voltage amplifier 72.

According to an embodiment of the present disclosure, the deQ circuit 50 includes a deQ network 74 and a distributed inductor L_{DPA}. The distributed inductor L_{DPA} may be provided on the conductive path 46 but outside the distributed PMIC 44, or be integrated into the distributed PMIC 44 and off the conductive path 46. The deQ network 74, on the other hand, is provided inside the main PMIC 42 and coupled to the conductive path 46 via the auxiliary voltage output 62. In this regard, the deQ network 74 is not on (a.k.a. off) the conductive path 46.

In an alternative embodiment, the distributed inductor L_{DPA} may be provided on the conductive path 46 but closer to the main PMIC 42. In this regard, FIG. 2B is a schematic diagram providing an exemplary illustration of the distributed power management circuit 40 wherein the distributed inductor L_{DPA} is provided outside the main PMIC 42 and on the conductive path 46. Common elements between FIGS. 2A and 2B are shown therein with common element numbers and will not be re-described herein.

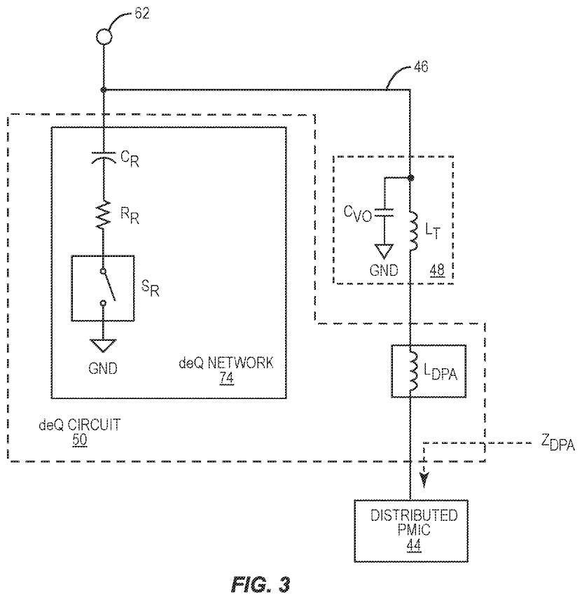

FIG. 3 is a schematic diagram providing an exemplary illustration of the deQ network 74 configured according to an embodiment of the present disclosure. Common elements between FIGS. 2A, 2B, and 3 are shown therein with common element numbers and will not be re-described herein.

The deQ network 74 includes a capacitor C_{R}, a resistor R_{R}, and a switch SR coupled in series between the auxiliary voltage output 62 and a ground (GND). In a non-limiting example, the deQ network 74 can be activated by closing the switch SR and deactivated by opening the switch SR. Notably, since the deQ network 74 is parallel to the equivalent capacitance C_{VO}, the deQ network 74 can reduce the Q-factor of the equivalent notch 48 when the deQ network 74 is activated.

As an example, an equivalent impedance Z(s) of the deQ network 74 can be calculated as in equation (Eq. 3) below.

$$Z ( s ) = \frac{\frac{1}{{C}_{VO} * s} + \frac{{R}_{R} * {C}_{R}}{{C}_{VO}}}{1 + \frac{{C}_{R}}{{C}_{VO}} + {R}_{R} * {C}_{R} * S} \qquad ( Eq . 3 )$$

By replacing “s” with “jω” (ω represents a pulsation frequency), the equation (Eq. 3) can be rewritten as equation (Eq. 4).

$$Z ( j ω ) = \frac{{R}_{R} * {( \frac{{C}_{R}}{{C}_{VO}} )}^{2}}{\begin{matrix}{( 1 + \frac{{C}_{R}}{{C}_{VO}} )}^{2} + \\ ( {R}_{R} * {C}_{R} * {ω}^{2} )\end{matrix}} + \frac{\frac{1 + \frac{{C}_{R}}{{C}_{VO}} + ( {R}_{R} * {C}_{R} * {ω}^{2} )}{( 1 + \frac{{C}_{R}}{{C}_{VO}} ) 2 + ( {R}_{R} * {C}_{R} * {ω}^{2} )}}{{jC}_{VO} * ω} \qquad ( Eq . 4 )$$

The Q-factor of Z(jω) can thus be determined as in equation (Eq. 5) below.

$$Q - factor = \frac{1 + \frac{{C}_{R}}{{C}_{VO}}}{{R}_{R} * {C}_{R} * ω} + {C}_{VO} * {R}_{R} * ω \qquad ( Eq . 5 )$$

It can be seen from equation (Eq. 5) that the Q-factor includes two terms, one as a function of 1/ω and another as a function of ω. To achieve the lowest Q-factor, it is necessary for the deQ network 74 to have the series resonance frequency f_{deQ} that satisfies the condition of dQ-factor/dω=0. Accordingly, the series resonance frequency f_{deQ} and the corresponding minimum Q-factor (denoted as “Q_{MIN}”) can be expressed as in equations (Eq. 6 and Eq. 7) below.

$${f}_{deQ} = \frac{\sqrt{1 + \frac{{C}_{VO}}{{C}_{R}}}}{2 π * {R}_{R} * \sqrt{{C}_{R} * {C}_{VO}}} \qquad ( Eq . 6 )$$

$${Q}_{MIN} = 2 * \sqrt{\frac{{C}_{VO}}{{C}_{R}} * ( 1 + \frac{{C}_{VO}}{{C}_{R}} )} \qquad ( Eq . 7 )$$

It can be seen from equation (Eq. 7), the Q_{MIN} can be further reduced by increasing the C_{R}, which is desirable. However, according to equation (Eq. 6), a higher C_{R} can also reduce the f_{deQ}, thus making the distributed inductor L_{DPA} a necessity in the deQ circuit 50. Herein, the distributed inductor L_{DPA} is employed to provide an opposite reactance of Z(jω) at the series resonance frequency f_{deQ}. In an embodiment, an optimum value of the distributed inductor L_{DPA} can be determined based on equation (Eq. 8) below.

$${L}_{DPA} = \frac{2 * {R}_{{R}^{2}} * {C}_{R}}{( 1 + \frac{{C}_{VO}}{{C}_{R}} ) * ( 2 + \frac{{C}_{R}}{{C}_{VO}} )} \qquad ( Eq . 8 )$$

With reference back to FIG. 2A, in addition to helping to achieve the Q_{MIN} at the series resonance f_{deQ}, the distributed inductor L_{DPA} also presents a higher impedance Z_{DPA} to the distributed PMIC 44, particularly to the distributed voltage amplifier 72. Understandably, the higher impedance Z_{DPA} can reduce current flow in the distributed voltage amplifier 72, thus helping to reduce energy waste in the distributed PMIC 44. In addition, the higher impedance Z_{DPA} can also isolate the distributed voltage amplifier 72 from the equivalent inductance L_{T} and the equivalent capacitance C_{VO}, thus helping to reduce potential distortion in the distributed voltage DV_{CC}. Further, the distributed inductor L_{DPA} can move the series resonance frequency f_{deQ} well inside a modulation bandwidth of the distributed voltage amplifier 72 to thereby minimize amplitude and phase changes of the distributed voltage DV_{CC} around the series resonance frequency f_{deQ}. As a result, it is possible to improve linearity, error vector magnitude (EVM), and adjacent channel leakage ratio (ACLR) of the distributed PMIC 44.

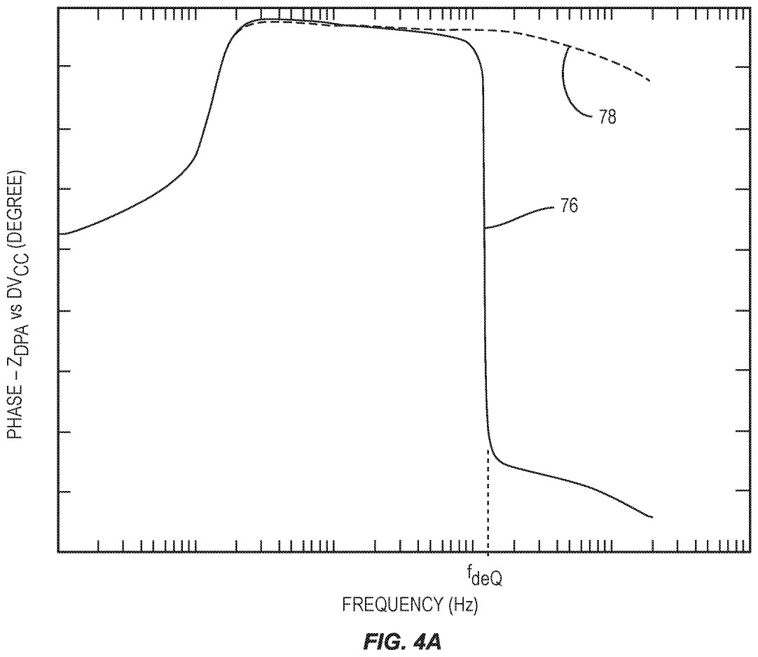

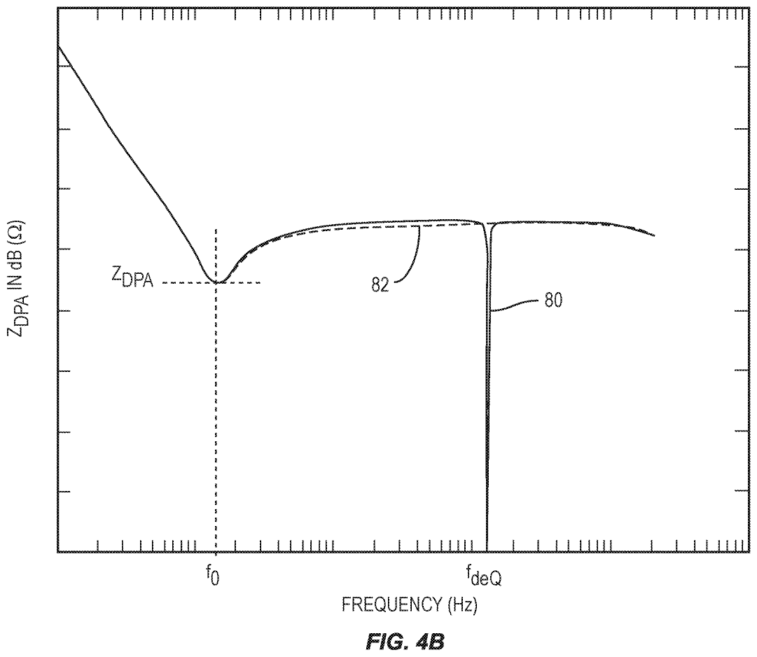

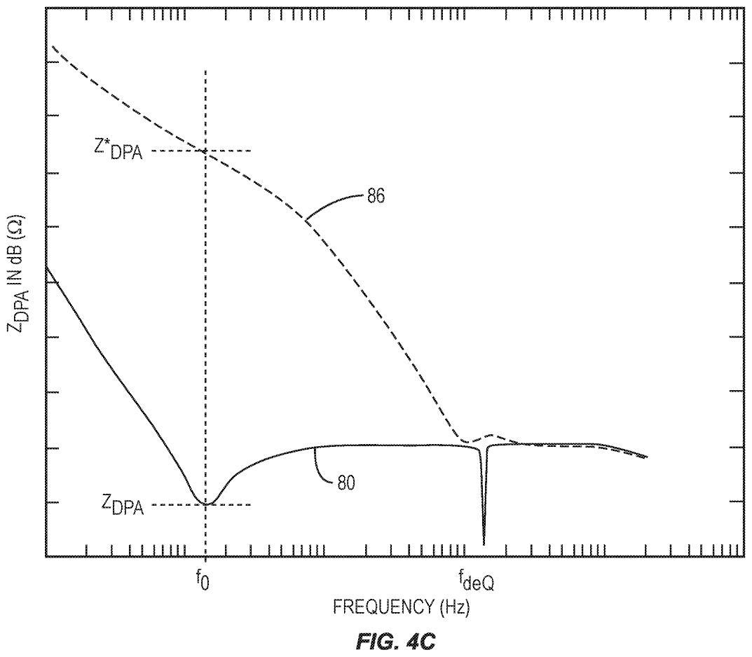

FIGS. 4A and 4B are graphic diagrams illustrating how the deQ circuit 50 in FIG. 3 can impact overall performance of the distributed power management circuit 40 of FIGS. 2A and 2B. Specifically, FIG. 4A is a graphic diagram illustrating a phase improvement provided by the deQ circuit 50 in FIGS. 2 and 3.

In FIG. 4A, a first curve 76 illustrates a relative phase between the impedance Z_{DPA} and the distributed voltage DV_{CC} without the deQ circuit 50 and a second curve 78 illustrates the relative phase between the impedance Z_{DPA} and the distributed voltage DV_{CC} with the deQ circuit 50. As shown, without the deQ circuit 50, the relative phase between the impedance Z_{DPA} and the distributed voltage DV_{CC} changes sharply at the series resonance frequency f_{deQ}. In contrast, with the deQ circuit 50, the relative phase between the impedance Z_{DPA} and the distributed voltage DV_{CC} remains stable at the series resonance frequency f_{deQ}.

FIG. 4B is a graphic diagram illustrating an improvement in the impedance Z_{DPA} provided by the deQ circuit 50 in FIGS. 2 and 3. Herein, a first curve 80 illustrates the impedance Z_{DPA} in decibel (dB) versus frequency without the deQ circuit 50 and a second curve 82 illustrates the impedance Z_{DPA} in dB versus frequency with the deQ circuit 50. As shown, without the deQ circuit 50, the impedance Z_{DPA} sharply drops at the series resonance frequency f_{deQ}. In contrast, with the deQ circuit 50, the impedance Z_{DPA} remains stable at the series resonance frequency f_{deQ}.

Notably, the impedance Z_{DPA} does drop at frequency f₀, independent of whether the deQ circuit 50 is employed. As described below, it is possible to correct the decreased impedance Z_{DPA} by increasing the modulation bandwidth (a.k.a. open loop gain) of the distributed voltage amplifier 72.

With reference back to FIG. 2A, the distributed PMIC 44 further includes a distributed control circuit 84. The distributed control circuit 84 can be configured to increase the modulation bandwidth of the distributed voltage amplifier 72 based on the distributed sense current DI_{SENSE}. Moreover, by determining proper values of the capacitor C_{R}, the resistor R_{R}, and the distributed inductor L_{DPA}, it is possible to move the series resonance frequency f_{deQ} of the deQ circuit 50 well into the increased modulation bandwidth of the distributed voltage amplifier 72, thus helping to correct the decreased impedance Z_{DPA} shown in FIG. 4B.

FIG. 4C is a graphic diagram illustrating an improvement in the impedance Z_{DPA} as a result of increasing the modulation bandwidth of the distributed voltage amplifier 72. Herein, a curve 86 illustrates an improved impedance Z′DPA at the frequency f₀ compared to the impedance Z_{DPA} shown in FIG. 4B.

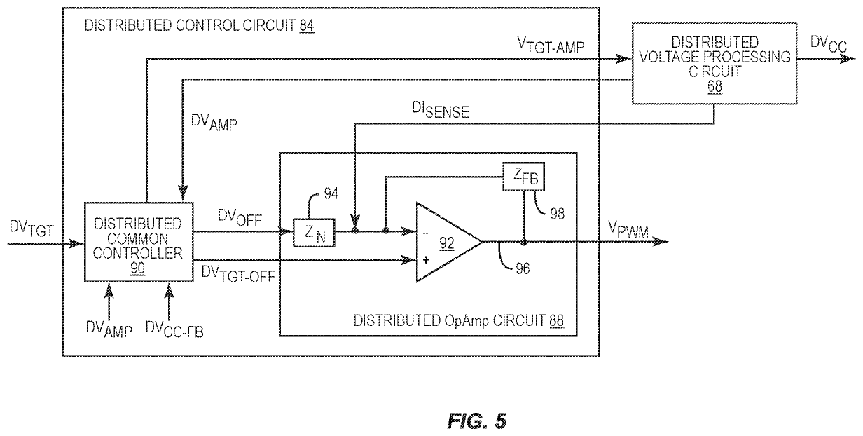

With reference back to FIG. 2A, the distributed control circuit 84 is further configured to determine the PWM target voltage V_{PWM} based on the distributed target voltage DV_{TGT}, the distributed initial voltage DV_{AMP}, and the distributed sense current DI_{SENSE}. FIG. 5 is a schematic diagram providing an exemplary illustration of the distributed control circuit 84 configured according to an embodiment of the present disclosure. Common elements between FIGS. 2 and 5 are shown therein with common element numbers and will not be re-described herein.

The distributed control circuit 84 includes a distributed operational amplifier circuit 88 and a distributed common controller 90. The distributed operational amplifier circuit 88 includes an operational amplifier 92. The operational amplifier 92 includes an inverted input terminal “−” that is coupled to the distributed common controller 90 via an input circuit 94. The operational amplifier 92 also includes a non-inverted input terminal “+” that is coupled directly to the distributed common controller 90. The operational amplifier 92 also includes an output terminal 96 that is coupled to the PWM modulator 66 in FIGS. 2A and 2B to thereby provide the PWM target voltage V_{PWM} to the PWM modulator 66. The output terminal 96 is further coupled to the inverted input terminal “−” via a feedback circuit 98.

The distributed common controller 90 receives the distributed target voltage DV_{TGT} from the main PMIC 42 in FIGS. 2A and 2B. Accordingly, the distributed common controller 90 can determine the distributed offset target voltage DV_{TGT-OFF} and the distributed offset voltage DV_{OFF}. In an embodiment, the distributed offset target voltage DV_{TGT-OFF} may be predefined in accordance with the distributed target voltage DV_{TGT} and stored in the distributed common controller 90. The distributed common controller 90 may also determine the distributed offset voltage DV_{OFF} based on the feedback of the distributed initial voltage DV_{AMP} and the distributed voltage DV_{CC-FB}. The distributed common controller 90 can then provide the distributed offset voltage DV_{OFF} and the distributed offset target voltage DV_{TGT-OFF} to the inverted input terminal “−” and the non-inverted input terminal “+” of the operational amplifier 92, respectively. Herein, the operational amplifier 92 further receives the distributed sense current DI_{SENSE} from the distributed voltage processing circuit 68 via the inverted input terminal “−” and, accordingly, generates the PWM target voltage V_{PWM} as shown in equation (Eq. 9) below.

$${V}_{PWM} = {D V}_{TGT - OFF} + {Z}_{FB} / {Z}_{IN} * ( {D V}_{TGT - OFF} - {D V}_{OFF} ) - {Z}_{FB} * {DI}_{SENSE} \qquad ( Eq . 9 )$$

In the equation (Eq. 9), ZIN represents a corresponding impedance of the input circuit 94 and Z_{FB} represents a corresponding impedance of the feedback circuit 98. The PWM target voltage V_{PWM} can cause the PWM modulator 66 to adapt the duty cycle signal 60 to thereby control the switcher circuit 54 to modulate the low-frequency current I_{DC} in accordance with the distributed target voltage DV_{TGT}. As a result, it is possible to reduce, or even eliminate, the distributed high-frequency current DI_{AMP} in the distributed PMIC 44, thus helping to improve efficiency of the distributed voltage amplifier 72 and reduce energy consumption in the distributed power management circuit 40.

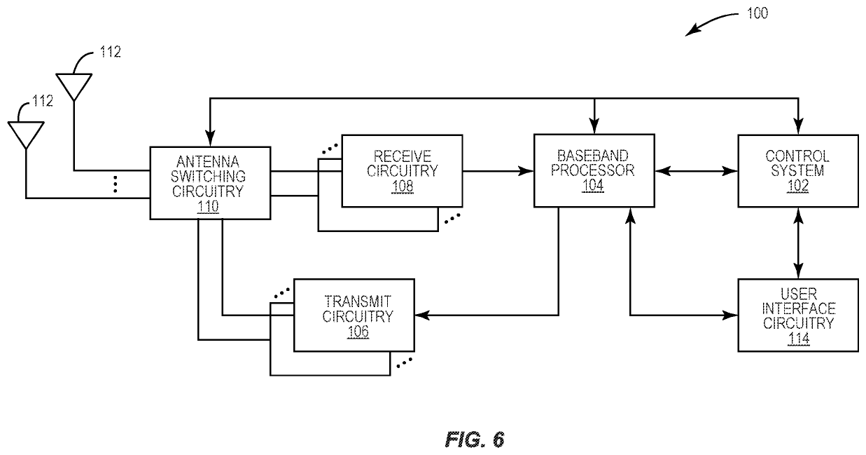

The distributed power management circuit 40 of FIGS. 2A and 2B can be provided in a user element to support the embodiments described above. In this regard, FIG. 6 is a schematic diagram of an exemplary user element 100 wherein the distributed power management circuit 40 of FIGS. 2A and 2B can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A distributed power management circuit comprising:
a distributed power management integrated circuit, PMIC, configured to generate a distributed voltage based on a distributed target voltage;
a main PMIC configured to generate the distributed target voltage and provide a low-frequency current to the distributed PMIC via a conductive path provided between the main PMIC and the distributed PMIC; and
a deQ circuit provided between the distributed PMIC and the main PMIC and configured to resonate at a series resonance frequency to reduce a quality factor, Q-factor, of an equivalent notch collectively caused by an equivalent inductance of the conductive path and an equivalent capacitance of the main PMIC.

2. The distributed power management circuit of claim 1, wherein the deQ circuit comprises:
a deQ network provided inside the main PMIC and coupled to the conductive path via an auxiliary voltage output; and
a distributed inductor provided outside the main PMIC.

3. The distributed power management circuit of claim 2, wherein the distributed inductor is provided as one of:
on the conductive path and outside the distributed PMIC; and
off the conductive path and inside the distributed PMIC.

4. The distributed power management circuit of claim 2, wherein the distributed inductor is provided on the conductive path and outside the main PMIC.

5. The distributed power management circuit of claim 2, wherein the distributed inductor is further configured to isolate the distributed PMIC from the equivalent inductance of the conductive path and the equivalent capacitance of the main PMIC.

6. The distributed power management circuit of claim 2, wherein the deQ network comprises a capacitor, a resistor, and a switch coupled in series between the auxiliary voltage output and a ground, the deQ network is activated when the switch is closed and deactivated when the switch is opened.

7. The distributed power management circuit of claim 6, wherein the capacitor, the resistor, and the distributed inductor are collectively selected to increase a modulation bandwidth of the distributed PMIC such that the series resonance frequency of the deQ circuit can fall within the modulation bandwidth of the distributed PMIC.

8. The distributed power management circuit of claim 2, wherein the main PMIC comprises:
a switcher circuit coupled to the auxiliary voltage output and comprising:
a multi-level charge pump, MCP, configured to generate a low-frequency voltage based on a duty cycle signal; and
a power inductor configured to induce the low-frequency current at the auxiliary voltage output based on the low-frequency voltage; and
a pulse-width modulation, PWM, modulator coupled to the MCP and configured to generate the duty cycle signal based on a PWM target voltage.

9. The distributed power management circuit of claim 8, wherein the distributed PMIC comprises:
a distributed voltage amplifier configured to:
generate a distributed initial voltage based on a distributed supply voltage and a distributed amplifier target voltage; and
generate a distributed sense current indicating a high-frequency current flowing through the distributed voltage amplifier;
a distributed offset capacitor coupled to the distributed voltage amplifier and the distributed inductor and configured to raise the distributed initial voltage by a distributed offset voltage to generate the distributed voltage at a distributed voltage output; and
a distributed control circuit configured to determine the PWM target voltage based on the distributed target voltage, the distributed initial voltage, and the distributed sense current.

10. The distributed power management circuit of claim 9, wherein the distributed control circuit comprises:
a distributed operational amplifier circuit coupled to the PWM modulator and configured to generate the PWM target voltage based on the distributed sense current, the distributed offset voltage, and a distributed offset target voltage; and
a distributed common controller coupled to the distributed operational amplifier circuit and configured to:
determine the distributed offset voltage based on feedback of the distributed voltage and the distributed initial voltage; and
determine the distributed offset target voltage based on the distributed target voltage.

11. The distributed power management circuit of claim 1, wherein the deQ circuit is further configured to reduce a peak voltage seen by the main PMIC to thereby protect the main PMIC from exceeding an inherently safe operating region.

12. A wireless device comprising:
at least one primary antenna provided on a first side of the wireless device;
at least one secondary antenna provided on a second side of the wireless device;
at least one primary power amplifier circuit configured to amplify a radio frequency, RF, signal based on a voltage for transmission via the at least one primary antenna;
at least one distributed power amplifier circuit configured to amplify the RF signal based on a distributed voltage for transmission via the at least one secondary antenna; and
a distributed power management circuit comprising:
a distributed power management integrated circuit, PMIC, configured to generate the distributed voltage based on a distributed target voltage and provide the distributed voltage to the at least one distributed power amplifier circuit;
a main PMIC configured to:
generate and provide the voltage to the at least one primary power amplifier circuit; and
generate the distributed target voltage and provide a low-frequency current to the distributed PMIC via a conductive path provided between the main PMIC and the distributed PMIC; and
a deQ circuit provided between the distributed PMIC and the main PMIC and configured to resonate at a series resonance frequency to reduce a quality factor, Q-factor, of an equivalent notch collectively caused by an equivalent inductance of the conductive path and an equivalent capacitance of the main PMIC.

13. The wireless device of claim 12, wherein:
the at least one primary power amplifier circuit is provided closer to the at least one primary antenna than to the at least one secondary antenna; and
the at least one distributed power amplifier circuit is provided closer to the at least one secondary antenna than to the at least one primary antenna.

14. The wireless device of claim 12, wherein the deQ circuit comprises:
a deQ network provided inside the main PMIC and coupled to the conductive path via an auxiliary voltage output; and
a distributed inductor provided outside the main PMIC.

15. The wireless device of claim 14, wherein the distributed inductor is provided as one of:
on the conductive path and outside the distributed PMIC; and
off the conductive path and inside the distributed PMIC.

16. The wireless device of claim 14, wherein the distributed inductor is provided on the conductive path and outside the main PMIC.

17. The wireless device of claim 14, wherein the distributed inductor is further configured to isolate the distributed PMIC from the equivalent inductance of the conductive path and the equivalent capacitance of the main PMIC.

18. The wireless device of claim 14, wherein the deQ network comprises a capacitor, a resistor, and a switch coupled in series between the auxiliary voltage output and a ground, the deQ network is activated when the switch is closed and deactivated when the switch is opened.

19. The wireless device of claim 14, wherein the main PMIC comprises:
a switcher circuit coupled to the auxiliary voltage output and comprising:
a multi-level charge pump, MCP, configured to generate a low-frequency voltage based on a duty cycle signal; and
a power inductor configured to induce the low-frequency current at the auxiliary voltage output based on the low-frequency voltage; and
a pulse-width modulation, PWM, modulator coupled to the MCP and configured to generate the duty cycle signal based on a PWM target voltage.

20. The wireless device of claim 12, wherein the deQ circuit is further configured to reduce a peak voltage seen by the main PMIC to thereby protect the main PMIC from exceeding an inherently safe operating region.
